(19) United States
(12) Patent Application Publication
(10) Pub. No.: US 2013/0029138 A1
(43) Pub. Date: Jan. 31, 2013

(54) GRAFTED POLYMER COATINGS

(71) Applicants: Freddy Bénard, Mons (BE); Philippe Dubois, Mons (BE); Marjorie Olivier, Mons (BE); Rony Snyders, Mons (BE); Laurent Denis, Mons (BE); Farid Khelifa, Mons (BE); Damien Thiry, Mons (BE); Fabian Renaux, Mons (BE)

(72) Inventors: Freddy Bénard, Mons (BE); Philippe Dubois, Mons (BE); Marjorie Olivier, Mons (BE); Rony Snyders, Mons (BE); Laurent Denis, Mons (BE); Farid Khelifa, Mons (BE); Damien Thiry, Mons (BE); Fabian Renaux, Mons (BE)

(73) Assignees: MATERIA NOVA, Mons (BE); UNIVERSITE DE MONS, Mons (DE)

(21) Appl. No.: 13/575,232

(22) PCT Filed: Jan. 26, 2011
(86) PCT No.: PCT/EP2011/051080

§ 371 Date: Oct. 12, 2012

(30) Foreign Application Priority Data
Jan. 27, 2010 (GB) 1001355.5
Jan. 28, 2010 (GB) 1001390.2

(51) Int. Cl. B32B 27/06; B32B 27/08; C23C 16/50; B82Y 30/00

(52) U.S. Cl. 428/336; 427/569; 427/578; 428/522; 428/473.5; 428/520; 428/447; 977/755

(57) ABSTRACT

A conventional polymer is grafted from a plasma polymer layer provided at a substrate surface by radical polymerisation initiated from plasma induced radicals present at or in the plasma polymer, particularly radicals provided during deposition of the plasma polymer.

This invention relates to grafted polymer coatings and particularly to a polymer coating deposited using a “grafting from” procedure from a plasma polymer.

International patent application WO 2006/097719 A1 discloses a polymer coating deposited using a “grafting from” procedure from a plasma polymer deposited on a substrate. In one embodiment the plasma polymer is chosen and deposited in such a way that it possesses functional groups which act as sites for a “grafting from” procedure. For example, a deposited plasma polymer may possess transferable halogen moieties which directly initiate Atom Transfer Radical Polymerisation (ATRP). In such embodiments, a surface initiated polymerisation procedure (“grafting from”) is undertaken directly after the plasma polymer deposition upon exposure of the plasma polymer to a suitable monomer(s) and suitable catalytic or mediating compound(s). In an alternative embodiment, the plasma polymer layer requires further derivatisation before it can initiate polymer growth. An example of this latter embodiment involves exposing a plasma polymer deposited from 4-vinylbenzyl chloride (4-VBC) to sodium diethyldithiocarbamate in ethanol to produce a dithiocarbamate functionalised 4-VBC surface having suitable initiator functionality to initiate photochemical Iniferter polymerisation when subsequently exposed to a methanolic solution of styrene monomer.

Whilst WO 2006/097719 A1 identifies a number of advantages and applications for the “grafting from” technique and the benefit of using a plasma polymer base layer from which the polymer coating is “grafted from” (thus avoiding some of the constraints associated with deposition of a polymer coating directly upon a surface of a substrate), its proposed coatings and manufacturing methods nevertheless suffer from a number of limitations.

One aim of the present invention is to overcome some of the limitations associated with known grafted polymer coatings and techniques.

In accordance with one of its aspects, the present invention provides a method of coating a substrate as defined in claim 1. According to this aspect of the invention, at least some of the active radicals are maintained “in an active state” that is to say in a state in which they are capable of initiating radical polymerisation of the conventional polymer without additional transformation or liberation. This is fundamentally different from the mechanism proposed in WO 2006/097719 according to which it is essential to provide particular functional groups in the plasma polymer which initially stabilise or trap the radicals in the functional group prior to a subsequently step in which the stabilised or trapped radicals are liberated so as to be able to initiate radical polymerisation.

Aspects of the invention relating to articles comprising polymer coatings are defined in other independent claims. The dependent claims define preferred or alternative embodiments.

In accordance with one aspect of the present invention, a plasma polymer serves as the base layer for the initiation of the deposition of a polymer layer for a “grafting from” or radical polymerisation process. The plasma polymer layer may be deposited on a wide variety of substrates including metal substrates (including steel and aluminium substrates) and non-metal substrates (including glass, silicon and polymer substrates). The substrate may be a sheet, a film, a surface or fibres. The plasma polymer layer may be firmly secured to the substrate, notably by cross-linking of the plasma polymer during its deposition.

The term plasma polymer is intended to denote an irregular three dimensional network of highly cross-linked molecular segments that may be formed, for example, by plasma enhanced chemical vapour deposition of an organic precursor, the high degree of cross-linking preferably contributing to properties including high mechanical resistance, thermal stability and high adherence to metal, glass and polymer substrates. The plasma polymer is preferably produced by exposing its precursor molecules to a plasma containing electrons whose energy is greater than the energy necessary to fragment the functional groups of the precursor molecule (for example anhydride functional groups).

The presence of active free radicals is induced in the plasma polymer, preferably during deposition of the plasma polymer. Such active free radicals are maintained in an active state so that they can initiate radical polymerisation when the plasma polymer is exposed to pre-cursors (monomers) of a conventional polymer. Thus, in this aspect of the invention, it is not necessary to specifically select the plasma polymer, its precursors and the deposition conditions such that the plasma polymer possesses functional groups which can subsequently act as sites for a “grafting from” procedure as radicals maintained in an active state within the plasma polymer (but not necessarily present as stable functional groups) initiate radical polymerisation of the desired polymer. For example, the plasma polymer precursors need not comprise specific functional groups, or if they do, such functional groups need not be maintained during formation of the plasma polymer to provide “grafting from” sites. Consequently, a significant simplification is provided in the nature and deposition of the plasma polymer, a wider choice of plasma polymers is made possible and the necessity of catalysing or derivising the plasma polymer to render it capable of initiating radical polymerisation is removed.

The radicals may be provided at the surface of the plasma polymer and/or in its bulk. Radicals provided below the surface of the plasma polymer may be particularly suited to initiating radical polymerisation of a precursor in a way which provides a high level of adhesion between the plasma polymer and a grafted conventional polymer (which, in this case, may be attached within the volume of the plasma polymer rather than just at the surface of the plasma polymer).

The excitation source used to induce the presence of active radicals within the plasma polymer may be a plasma generator, for example a radio frequency coil. The plasma generator may be used in capacitive (rather than inductive) mode as under at least some conditions this may favourite generation of a large number of radicals. Possible alternative or additional excitation sources include electromagnetic wave generators, a source of gamma radiation and a source of electron radiation.

Preferably, the plasma polymer is deposited on a substrate in a controlled atmosphere, for example a reduced pressure atmosphere substantially free of oxygen and/or nitrogen and/or other reactive species which would tend to react with and/or deactivate free radicals induced in the plasma polymer. The substrate may be maintained in a controlled atmosphere until exposed to the polymer precursors (monomers) of the conventional polymer to be deposited. This may be achieved, for example, by introducing the conventional polymer precursors (monomers) in to the enclosure in which the plasma polymer is deposited (for example at the end of a plasma polymer deposition phase) or moving the substrate to a different enclosure at which the conventional polymer precursors (monomers) are deposited through a controlled atmosphere, for example in a multi chamber on-line coater.

Preferably, the plasma polymer is a highly reticulated plasma polymer. The term “highly reticulated plasma polymer” as used herein means a plasma polymer in respect of which:
the average number of carbon atoms in a linear chain between reticulation nodes is less than 20, and/or
For the average hydrocarbon fragment expressed in the form CxHy, x is ≦20.

This may be determined by ToF-SIMS analysis and suitable data processing.

With respect of the highly reticulated plasma polymer:
the average number of carbon atoms in a linear chain between reticulation nodes may be less than 15, less than 10, less 8, and is preferably less than 6 and more preferably less than 5; and/or
for the average hydrocarbon fragment expressed in the form CxHy, x may be ≦15, ≦10, ≦8, and preferably x is ≦6, more preferably x is ≦5.

Preferably, the plasma polymer is devoid or substantially devoid of functional groups which could potentially be activated to act as “grafting from” sites.

The polymer coating, notably the conventional polymer, preferably provides a functional coating adapted to the substrate and/or its use. For example:

| | Possible function(s) provided by the polymer |
|---|---|
| Possible substrate | coating |
| Steel | Corrosion protection |
| | Scratch protection |
| | Aesthetic appearance |
| Aluminium | Corrosion protection |
| | Scratch protection |
| | Aesthetic appearance |
| Ceramic | Chemical protection |
| Glass | Scratch protection |
| | Aesthetic appearance |
| | Thermal and optical properties |
| Polymer material | Scratch protection |
| | Gas barrier properties and/or “impermeability” |
| | Biocompatibility |
| | Thermal properties |

With respect to the use of the plasma polymer precursors comprising one or more precursors selected from the group consisting of allylamine, acrylate, butyl acrylate, methyl acrylate, ethyl acrylate, 2-ethyl hexyl acrylate, glycidyl methacrylate, aromatic and aliphatic acrylate derivatives, aromatic and aliphatic methacrylate derivatives, CH₄/N₂, silane derivatives (eg. Hexamethylenedisiloxane), fluorine derivatives (eg. Difluoroethylene, tetrafluoroethylene), aliphatic and aromatic organic derivatives, aliphatic or aromatic alcohols, saturated or unsaturated alcohols, aliphatic or aromatic amines, saturated or unsaturated amines, ketones, acids, aldehydes, esters, anhydrides, these may provide one or more of the following advantages:

| Plasma polymer | |
|---|---|
| precursors | Advantage(s) |
| Allylamine | Predictable and easily controllable deposition |
| | results; possible to detect a nitrogen signal and |
| | its disappearance due to the growth of the |
| | radical polymer layer |
| Butyl acrylate, Propyl | Possibility to stop the plasma and to immediately |
| acrylate, Ethyl | start the radical polymerisation with the |
| acrylate, Methyl | precursor being used as a monomer precursor |
| acrylate, Ethylhexyl | for both the plasma polymer and the |
| acrylate, Glycidyl | conventional polymer |
| methacrylate | |
| Allylamine/Acrylate | Possibility to progressively switch from 100% |
| | allylamine to 100% acrylate precursor vapour |
| | into the deposition device |
| Vinyl-acetate | Possibility to stop the plasma and to immediately |
| | start the radical polymerisation with the |
| | precursor being used as a monomer precursor |
| | for both the plasma polymer and the |
| | conventional polymer. |
| | Possibility to graft functionalities on the |
| | conventional polymer |
| CH₄/N₂ | Predictable structure of the film |
| Aliphatic or aromatic | Volatile liquid precursor; Easily evaporated and |
| alcohols | injectable in the plasma |
| Hexa- | Possibility to endow dielectric properties |
| methylenedisiloxane | |
| Fluorine based | Possibility to improve the hydrophobicity of a |
| precursor | substrate |

The conventional polymer layer may be provided by one or more monomers deposited, for example selected from the following acrylate monomers:

| Monomer for deposition of | |
|---|---|
| conventional polymer | Possible advantage(s) |
| Butyl acrylate | Useful Tg: Tg (Poly(butyle acrylate)) = |
| | 218 K |
| Propyl acrylate | Useful Tg: Tg (propyl (acrylate)) = 225 K |
| Ethyl acrylate | Useful Tg: Tg (poly(ethyl acrylate)) = 249 K |
| Methyl acrylate | Useful Tg: Tg (poly(methyl acrylate)) = |
| | 279 K |
| | Highly reactive; initiation of polymerisation |
| | on the surface and in the body of the plasma |
| | polymer |
| Ethylhexyl acrylate | Useful Tg: Tg (poly(ethylhexyl acrylate)) = |
| | 209 K |
| Glycidyl methacrylate | Availability of an epoxy ring on the polymer |
| | chain for further reactions and graftings |
| Vinylimidazole | Corrosion protection of copper |
| N-isopropylacrylamide | Cryosensitivity of the polymer poly(nipaam) |
| (Nipaam) | |
| N,N′- | pH sensitivity of the poly(MADAME) |
| dimethylaminomethacrylate | |
| (MADAME) | |

Acrylate monomers may be used to provide a “scratch resistant” and/or “self healing” functional coating due to the thermo-mechanical properties of a polymer layer obtained by radical polymerisation of these acrylates. Where the glass transition temperature Tg of such a layer is lower than ambient temperature, the mobility of the polymer chains at ambient temperature permits them to go back to their initial configuration in the case of a scratch (ie to have a “self healing” function).

An unsaturated monomer able to polymerise via free-radical polymerisation reaction may be used as a precursor for the conventional polymer layer. The precursor(s) for the conventional polymer layer may be selected from:
acrylic family (and corresponding methacrylic derivatives): particularly acrylic acid (and all related salts), acrylonitrile, acrylamide (N,N-substituted or not), acrylate (whatever the ester substituent: linear, substituted and even functionalized by alcohol, amine, (poly)ether, epoxy, thiol, azide function(s), carbon double (or triple) bond(s));
styrenic monomers: styrene, and styrene substituted in ortho, meta and/or para positions;
vinyl pyridines (vinyl 2- or vinyl 4-pyridine);
dienes: butadiene, isoprene, chloroprene, neoprene;
vinyl chloride, vinylidene dichloride;
vinyl acetate and derivatives;
fluorinated unsaturated monomers (e.g. vinylidene difluoride, vinyl tetrafluoride).

The conventional polymer may comprise a copolymer derived from two or more of such precursors.

The conventional polymer is preferably secured to the plasma polymer by covalent bonding.

The term conventional polymer is intended to indicate a polymer which is not a plasma polymer, and comprising repeating structural units connected by covalent chemical bonds.

In one embodiment, the precursors of the conventional polymer are the same as the precursors of the plasma polymer. This not only simplifies the manufacturing process but, when desired, is one way of producing a graded plasma/conventional polymer. Such a graded structure may have a highly cross-linked plasma polymer deposited on the substrate with the structure of the polymer changing progressively to a conventional polymer as the distance from the substrate surface increases. This may provide a gradient transition between the plasma polymer and the conventional polymer, ie a gradual transition rather than a single step transition between the plasma polymer and the conventional polymer, particularly where the conventional polymer is arranged as a layer over the plasma polymer. Such a graded structure may provide particularly good securing of the conventional polymer to the plasma polymer. A process in which the same precursors are used for the plasma polymer and the conventional polymer and in which radical polymerisation occurs simultaneously with plasma polymerisation may produce such a coating, for example by gradually reducing the power applied during plasma polymerisation and preferably allowing for radical polymerisation to continue after the plasma has been discontinued.

In some embodiments, the following are absent from the ends of at least some of (preferably absent from the majority of and more preferably absent from substantially all of) the conventional polymer chains: chlorine, bromine, thiocarbamate groups, and nitroxy groups. Alternatively or additionally, in some embodiments the following are absent or substantially absent from the plasma polymer and/or the interface between the plasma polymer and the conventional polymer: halogens derivatives, copper derivatives, heavy metals derivatives, thiocarbamate groups, and nitroxy groups. Such materials or groups, which are essential for the coatings of conventional polymers grafted from plasma polymers of WO 2006/097719 A1 are undesirable from a perspective of cost and/or easy of handling and/or stability and/or environmental aspects and may be avoided using the present invention. Thiocarbamate groups and/or fluorine groups may also be absent in the same ways.

The plasma polymer may be in direct contact with the substrate or a coating layer may be provided between the substrate and the plasma polymer.

A step of surface preparation of the substrate to facilitate and/or enhance deposition of the plasma polymer may be provided, for example a surface cleaning and/or surface refreshing step. This may be achieved by subjecting the substrate surface to an oxygen/argon plasma.

Non-limiting examples of aspects of the invention will now be described with reference to:

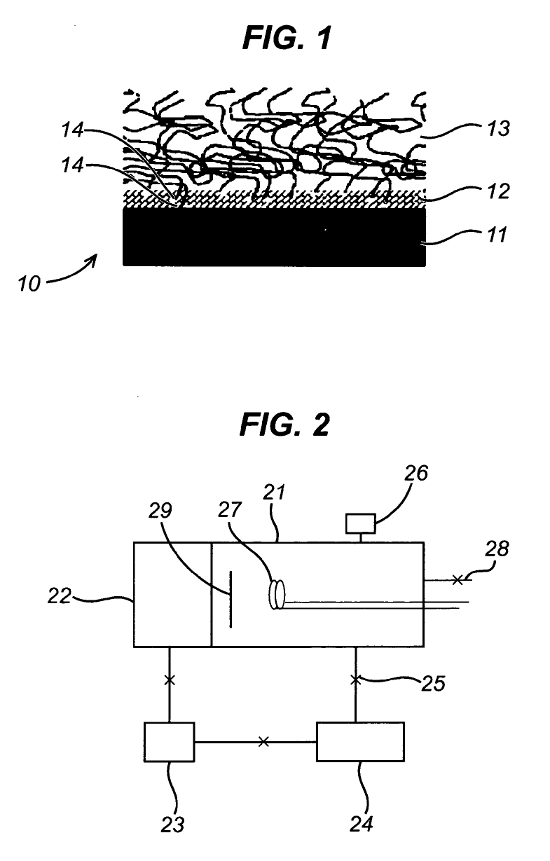

FIG. 1: which is a schematic side view (not to scale) of a substrate having a conventional polymer layer grafted from a plasma polymer;

FIG. 2: which is a schematic representation of a laboratory arrangement for producing such an article;

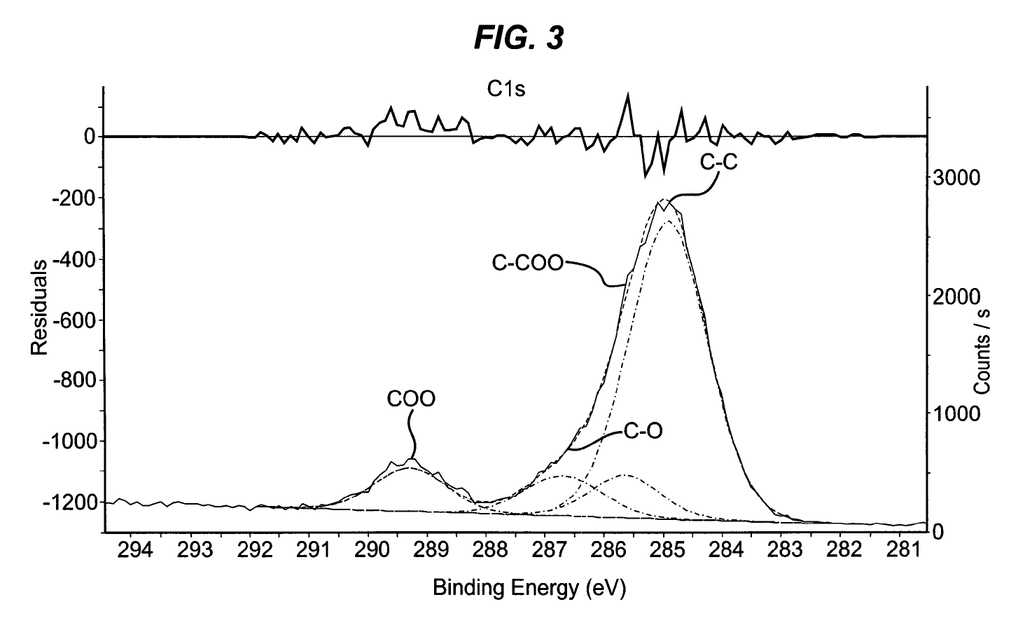

FIG. 3: which is a XPS Spectrum of a substrate surface following deposition of a plasma polymer and subsequent deposition of a conventional polymer;

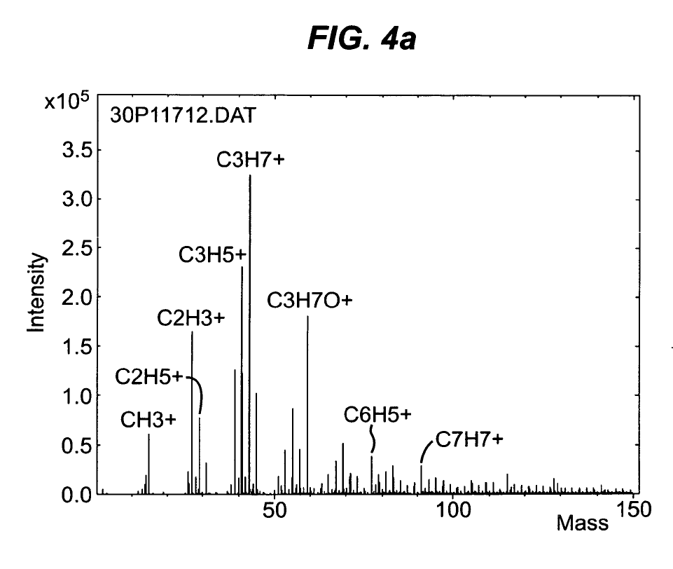

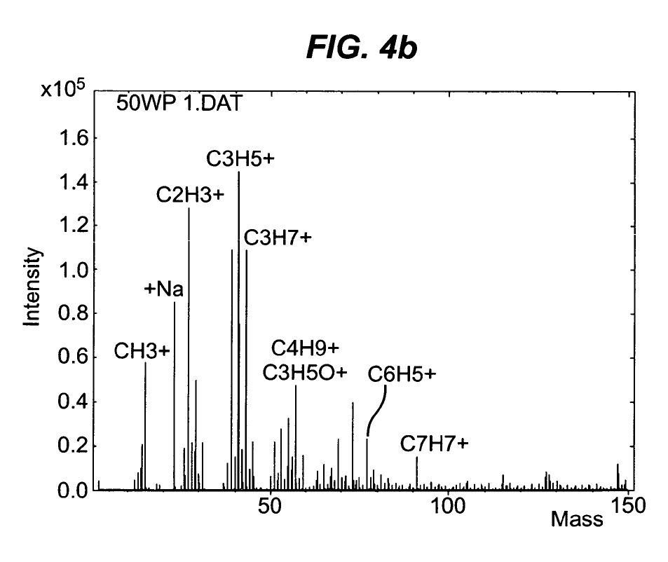

FIGS. 4a and 4b: which are representations of ToF-SIMS analysis;

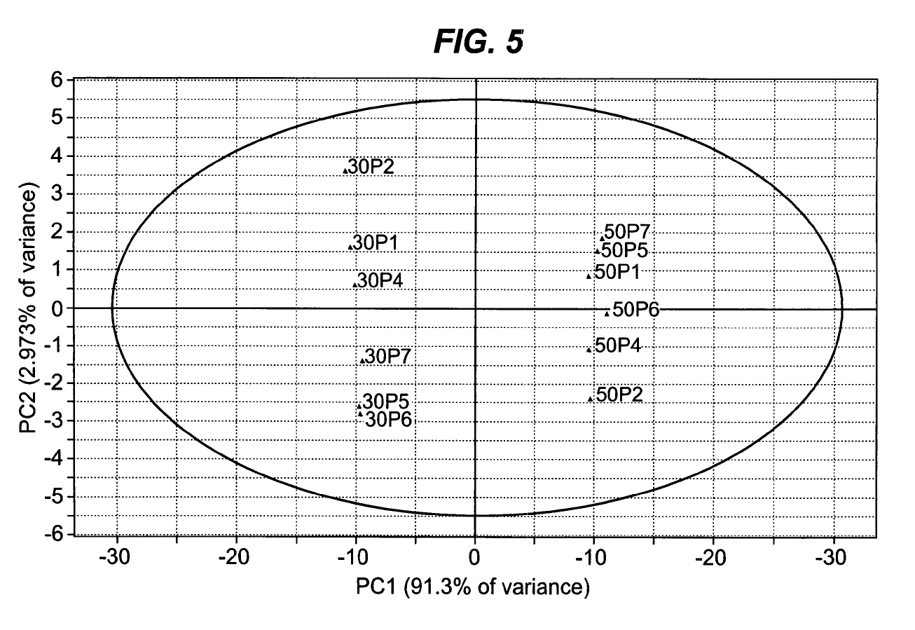

FIG. 5: which is a representation of a PCA analysis; and

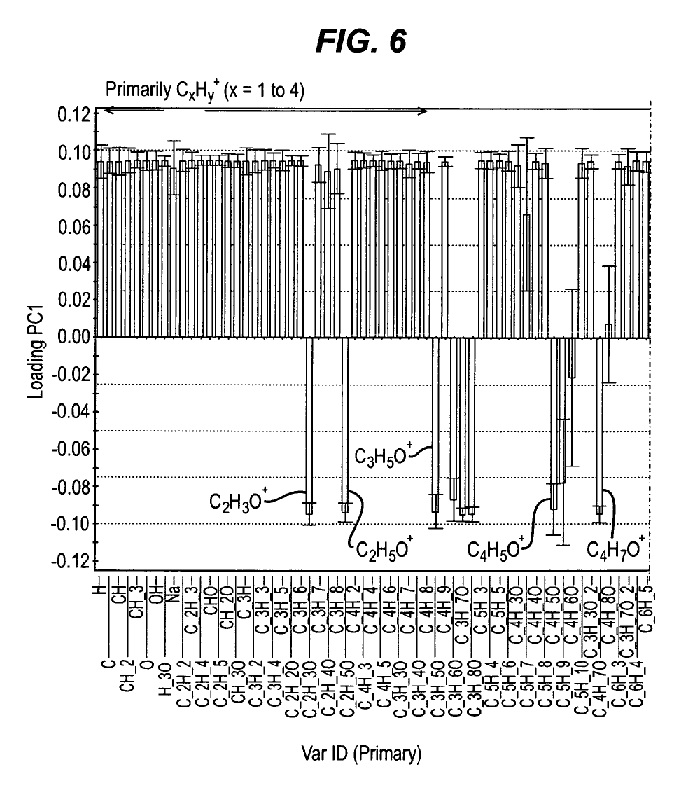

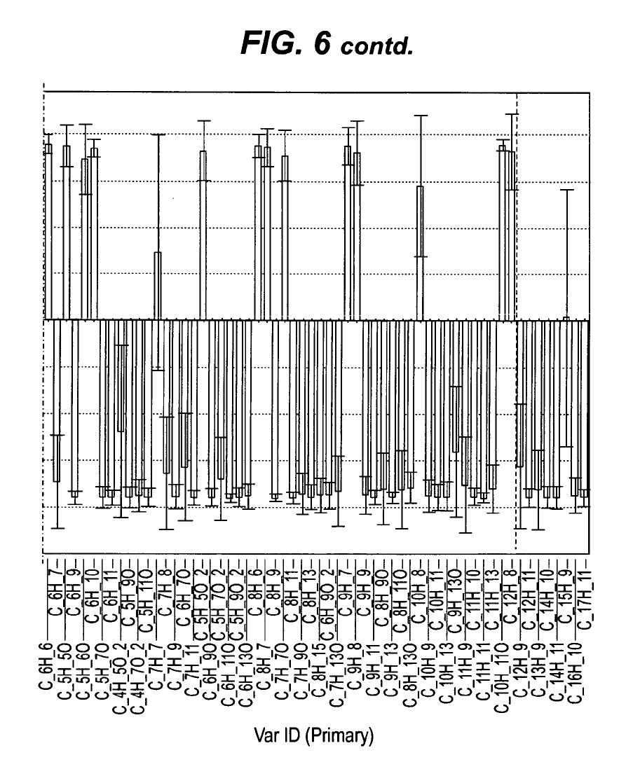

FIG. 6: which is a graphical representation of the loadings from the PCA analysis.

The article 10 of FIG. 1 comprises a substrate 11 carrying a plasma polymer 12 on at least a part of at least one surface. A conventional polymer 13 forming a functional layer is grafted from the plasma polymer. The plasma polymer will typically have a thickness of greater than 30 nm and or less than 500 nm; the conventional polymer 13 will typically have a thickness of greater than 10 nm and/or less than 20 μm.

Radical polymerisation of the conventional monomer is initiated from radicals 14 present at and below the surface of the plasma polymer layer 12.

The article of FIG. 1 may be produced using the equipment illustrated schematically in FIG. 2 which comprises:
A sealable vacuum deposition chamber 21;
an entry zone or SAS 22 which can be isolated from the deposition chamber 21 via a sealed draw so as to allow a sample to be introduced in to the deposition chamber without venting the deposition chamber to ambient conditions;
a sample carrier (not shown) which can be used to transfer a substrate to be coated between the SAS 22 and the deposition chamber 21;
A primary pump 23 and a turbo molecular pump 24 connected in series and capable of evacuating the deposition chamber 21 to a residual pressure of 10⁻⁷ Torr via a butterfly valve 25 (note that the primary pump 23 may be used separately from the turbo molecular pump 24 to rapidly evacuate the SAS 22 for example from atmospheric pressure to a pressure of about 10⁻² Torr, for example over the duration of a minute);
A pressure gauge 26 configured to sense the pressure in the deposition chamber 21;
A water cooled radio frequency induction coil 27 positioned within the deposition chamber 21 and configured for use in inductive and capacitive modes at a power of up to 1000 W and coupled to a signal generator which may be adjusted to provide a pulsed signal with control of peak power, effective cycle and pulse frequency;
An entry port 28 for polymer precursor to be introduced in to the deposition chamber 21 associated with a flow meter (not shown) and a variable entry valve.

The following steps and conditions may be used to deposit desired coatings on a substrate arranged in deposition chamber 21:

In preparation for a cleaning step, the pressure in the deposition chamber is lowered to 10⁻⁶ Torr. Argon and oxygen are injected into the deposition chamber with the following flows: argon flow of 25 standard cm³ by minute (sccm); oxygen flow of 25 sccm. The plasma is activated when pressure is regulated to 50 mTorr. The plasma is in capacitive mode with a power of 25 W and a self-bias is measured on the substrate. The cleaning step is operated during 10 minutes.

After the cleaning step, the pressure is lowered to 10⁻⁵ Torr in order to avoid the presence of contaminant species like oxygen or water vapour.

For the deposition of the plasma film, the precursor is vaporised into the chamber with a flow rate of 2.5 sccm. The pressure is regulated to 50 mTorr.

The plasma during the deposition of the plasma polymer is in capacitive and continuous mode to raise the amount of radical in the plasma polymer. The precursor is ethyl acrylate. The power of the plasma is higher than 10 W and lower than 500 W, preferentially higher than 25 W and lower than 100 W. The deposition step lasts more than 30 seconds and less than 3 minutes, preferentially more than 1 minute and less than 2 minutes.

For the deposition step of the conventional polymer, the plasma is cut off and the vaporisation of the precursor is maintained. The pressure is raised to a value higher than 100 mTorr. The deposition step of the conventional polymer lasts more than 10 sec and less than 24 hours.

The following tests were run:

### EXAMPLE 1

Using the equipment of FIG. 2, a silicium substrate 29 was arranged in the deposition chamber 21 and a plasma polymer followed by a conventional polymer were deposited on the substrate using the following sequential steps:

Step 1:

Cleaning and/or preparation of the surface of the substrate using the following conditions:

Pressure and gas mixture: 50 mTorr; argon flow of 25 sccm; oxygen flow of 25 sccm

Plasma coil mode and conditions: Capacitive; 25 W, estimated self-bias: −410V.

Duration: 10 minutes

Step 2:

Deposition of plasma polymer:

Pressure and gas mixture: 50 mTorr; estimated ethyl acrylate flow of 2.5 sccm

Plasma coil mode and conditions: Capacitive and continuous; 50 W, estimated self-bias of −580V.

Duration: 5 minutes

### EXAMPLE 2

Using the equipment of FIG. 2, a silicium substrate 29 was arranged in the deposition chamber 21 and a plasma polymer followed by a conventional polymer were deposited on the substrate using the following sequential steps:

Step 1:

Cleaning and/or preparation of the surface of the substrate using the following conditions:

Pressure and gas mixture: 50 mTorr; argon flow of 25 sccm; oxygen flow of 25 sccm

Plasma coil mode and conditions: Capacitive; 25 W; self-bias −422 V

Duration: 10 minutes

Step 2:

Deposition of plasma polymer:

Pressure and gas mixture: 50 mTorr; estimated ethyl acrylate flow of 2.5 sccm

Plasma coil mode and conditions: Capacitive and continuous; 50 W; self bias −583 V

Duration: 1.5 minutes

Step 3:

Deposition of conventional polymer:

Pressure and gas mixture: 100 mTorr; continuous ethyl acrylate vaporisation after stopping the plasma

Plasma coil mode and conditions: Off

Duration: 21.5 hours

### EXAMPLE 3

Using the equipment of FIG. 2, a silicium substrate 29 was arranged in the deposition chamber 21 and a plasma polymer followed by a conventional polymer were deposited on the substrate using the following sequential steps:

Step 1:

Cleaning and/or preparation of the surface of the substrate using the following conditions:

Pressure and gas mixture: 50 mTorr; argon flow of 25 sccm; oxygen flow of 25 sccm

Plasma coil mode and conditions: Capacitive; 25 W; Bias −417 V

Duration: 10 minutes

Step 2:

Deposition of plasma polymer:

Pressure and gas mixture: 50 mTorr; estimated ethyl acrylate, flow of 2.5 sccm

Plasma coil mode and conditions: Capacitive and continuous; 50 W; Bias −587 V

Duration: 1.5 minutes

Step 3:

Deposition of conventional polymer:

Pressure and gas mixture: 3.3 Torr; continuous ethyl acrylate vaporisation after stopping the plasma

Plasma coil mode and conditions: Off

Duration: 22 hours

In each example, each step in the process followed immediately from the previous step; after completion of the last step, the sample was removed from the deposition chamber and analysed. The ethyl acrylate vapour was supplied from a reservoir connected to the polymer entry port.

For examples 2 and 3, at the end of step 2 (deposition of plasma polymer) the plasma was stopped but the vaporisation and supply of the ethyl acrylate precursor was continued. On example 2, when step 3 of the experiment was stopped after 21.5 hours it was observed that the ethyl acrylate reservoir was empty.

An XPS spectrum of the product from example 1 showed a signal at 287.9 eV characteristic of ketone functions. Although the chemical precursor did not contain ketone functionalities, because of the fragmentation of the precursor molecules in the plasma during the deposition process ketone functions are formed and trapped in the film. Therefore, in our synthesis conditions, the signal of ketone functions at 287.9 eV is characteristic of the ethyl acrylate plasma polymer film.

An XPS spectrum of the product from example 2 revealed a ketone signal at 288.1 eV and a new signal at 289.3 eV. Following the literature, this new signal at 289.3 eV is representative of the acrylate function. The appearance of this signal demonstrates that the conventional poly(acrylate) have been grafted on the plasma polymer.

Taking into account the XPS analysis depth (˜10 nm) and the XPS spot (˜1 mm²), the occurrence of both these signals at 288.1 eV and at 289.3 eV could mean that the conventional poly(acrylate) layer is either thinner than 10 nm or inhomogeneous in thickness or both.

The spectrum from an XPS analysis of the product from example 3 is shown in FIG. 3. This does not show the signal corresponding to ketone functions. Nevertheless, it clearly shows signals at 289.3 eV, 286.7 eV and 285.5 eV. Following the literature, these signals are attributed to O—C═O, C—O functions and to the carbon in a of a carbonyl group (C—COO, C—C═O), respectively. As already mentioned, the signal at 289.3 eV is particularly representative of the acrylate function. The atomic ratio of each signal is about 7%.

The presence of the acrylate signal and the occurrence of these signals in the same proportions clearly demonstrates the presence of conventional poly(acrylate) at the surface of the sample. The absence of the ketone signal reveals that the conventional poly(acrylate) layer is homogenous through the area analysed (˜1 mm²). Moreover, taking into account the XPS analysis depth (˜10 nm), it also demonstrates that the conventional poly(acrylate) layer thickness is higher than 10 nm.

### EXAMPLE 4a AND 4b

Two isopropanol plasma polymer films were deposited to investigate differences between a plasma polymer film deposited at a power of 50 W in capacitive mode (example 4b which was found to be highly reticulated) and a plasma polymer film deposited at a lower power of 30 W in inductive mode (example 4a).

ToF-SIMS spectral analysis of these sample films are shown in FIG. 4a (example 4a) and 4b (example 4b). It can be seen that the intensity of the peak corresponding to C₃H₇O⁺ (m/z=59) is greater for example 4a than for example 4b; this suggests that the plasma polymer deposited at lower power has more functional groups present. It can also be seen that the peaks corresponding to C₆H₅⁺ and C₇H7⁺ are greater for the plasma polymer deposited at higher power (example 4b) and that the intensity of the C₂H₃⁺ peak of example 4b is greater than the group of C₃ peaks of example 4a; this suggests greater reticulation of the example 4b plasma polymer compared to that of example 4a.

A PCA (principal component analysis) was conducted on the intensity of the peaks from the Tof-SIMS analysis using SIMCA software. Six points were recorded for each of example 4a and 4b and the PCA analysis allowed the definition of two principal components with the first principal component PC1 taking account of 91.3% of the variance. The PCA analysis is represented graphically in FIG. 5 which shows a clear separation between the points from example 4a (prefixed 30P) which are located at PC1<0 compared with the points from example 4b (prefixed 50P) which are located at PC1>0.

A representation of the loadings from the PCA analysis is shown in FIG. 6, the peaks shown in the bottom half of FIG. 6 corresponding to example 4a and those shown in the top half corresponding to example 4b. These representations show that for example 4b peaks up to C₄ represent the most significant proportion of the peaks. Example 4a is characterised by peaks of CₓH_{y}O_{z}⁺ and by peaks at higher mass than for example 4b. This indicates that compared with example 4a, example 4b which was deposited at higher power has less functional groups and comprises primarily shorter hydrocarbon chains.

A calculation of the average hydrocarbon fragment taking account of the lowest loading limit of 0.90 gave:
for example 4a C_{10.04}H_{10.64}
for example 4b C_{4.27}H_{4.90}

This shows that the average hydrocarbon fragment of example 4b is significantly smaller than that of example 4a, furthermore, a comparison of the PCA analysis for examples 4a and 4b shows that the more representative or characteristic peaks for example 4a are oxygenated fragments characteristic of the precursor, indicating a lower level of reticulation for example 4a and a greater level of reticulation for example 4b.

It should be noted that the power delivered to the system for deposition of the plasma polymers of examples 4a and 4b was significantly greater than the average power of 0.26 W used in the examples of WO 2006/097719 A1.

1. A method of coating a substrate comprising the steps of:
depositing a plasma polymer at a surface of the substrate from plasma polymer precursors;
inducing the presence of active radicals within the plasma polymer by subjecting the plasma polymer and/or the plasma polymer precursors to an excitation source;
maintaining at least some of the active radicals in an active state suitable for initiating radical polymerisation;
exposing the plasma polymer including the active radicals maintained in an active state to a conventional polymer precursor capable of undergoing radical polymerisation;
allowing radical polymerisation of the conventional polymer precursor to occur, initiated from the maintained active radicals, to create a conventional polymer from the conventional polymer precursor which is bonded to the plasma polymer.

2. A method in accordance with claim 1, in which inducing the presence of active radicals within the plasma polymer occurs during deposition of the plasma polymer.

3. A method in accordance with claim 1, in which the maintaining of at least some of the active radicals in an active state suitable for initiating radical polymerisation comprises maintaining the plasma polymer within a controlled atmosphere.

4. A method in accordance with claim 1, in which the plasma polymer precursor(s) comprises one or more precursors selected from the group consisting of allylamine, acrylate, butyl acrylate, propyl acrylate, ethyl acrylate, methyl acrylate, 2-ethylhexyl acrylate, glycidyl methacrylate, aromatique and aliphatic acrylate derivatives, aromatique and aliphatic methacrylate derivatives, CH4/N2, silane derivatives, hexamethylenedisiloxane, fluorine derivatives, aliphatic and aromatic organic derivatives, aliphatic and aromatic alcohols, saturated and unsaturated alcohols, aliphatic and aromatic amines, saturated and unsaturated amines, ketones, acids, aldehydes, esters, anhydrides.

5. A method in accordance with claim 1, in which the conventional polymer precursor(s) comprises one or more precursors selected from the group consisting of: an unsaturated monomer able to polymerise via free-radical polymerisation; an acrylic or corresponding methacrylic derivative; an acrylic acid (and any related salts); an acrylonitrile; an acrylamide (N,N-substituted or not); an acrylate (whatever the ester substituent: linear, substituted and even functionalized by alcohol, amine, (poly)ether, epoxy, thiol, azide function(s), carbon double (or triple) bond(s)); butyl acrylate, propyl acrylate, ethyl acrylate, methyl acrylate; a styrenic monomer (including styrene and styrene substituted in ortho, eta and/or para positions); a vinyl pyridine (including vinyl 2- and vinyl 4-pyridine); a diene (including butadiene, isoprene, chloroprene, neoprene); a vinyl chloride (including vinylidene dichloride); a vinyl acetate (including derivatives); a fluorinated unsaturated monomers (including vinylidene difluoride, vinyl tetrafluoride).

6. A method in accordance with claim 1, in which any functional groups present in the plasma polymer precursors which could potentially act as “grafting form” sites are substantially destroyed during deposition of the plasma polymer.

7. A product of the method of claim 1.

8. A product comprising:
a substrate;
a highly reticulated plasma polymer secured to the substrate in respect of which the average number of carbon atoms in a linear chain between reticulation nodes is less than 20 and/or for the average hydrocarbon fragment expressed in the form CxHy, x is ≦20; and
a conventional polymer secured to the plasma polymer.

9. A product comprising:
a substrate;
a plasma polymer secured in the substrate; and
a conventional polymer secured in the plasma polymer;
in which the following are absent from the ends of at least some of the conventional polymer chains; chlorine, bromine, thiocarbamate groups, and nitroxy groups.

10. A product comprising:
a substrate;
a plasma polymer secured in the substrate; and
a conventional polymer secured in the plasma polymer;
in which the following materials and groups are absent from the plasma polymer and/or the interface between the plasma polymer and the conventional polymer: halogens derivatives, copper derivatives, heavy metals derivatives, thiocarbamate groups, and nitroxy groups.

11. A product comprising:
a substrate;
a plasma polymer secured in the substrate; and
a conventional polymer secured in the plasma polymer;
in which there is a gradient transition between the plasma polymer and the conventional polymer.

12. A product in accordance with claim 8, in which the plasma has a thickness in the range 30 nm to 500 nm.

13. A product in accordance with claim 8, in which the polymer coating provides a functional layer select from the group consisting of a self-healing layer, a scratch resistant layer, a corrosion protection layer, a decorative layer, a barrier layer, an impermeable layer, a hydrophilic or hydrophobic layer and a non-fouling layer.

14. A product in accordance with claim 8, in which the conventional polymer comprises a polymer selected from the group consisting of: acrylic, styrenic, dienic and halogen based ethylenic polymers and/or has a thickness in the range 10 nm to 10 μm.

15. A product in accordance with claim 8, in which the plasma polymer is a highly reticulated plasma polymer in respect of which the average number of carbon atoms in a linear chain between reticulation nodes is less than 20 and/or for the average hydrocarbon fragment expressed in the form CxHy, x is ≦20.
